(19) United States
(12) Patent Application Publication
(10) Pub. No.: US 2025/0069899 A1
(43) Pub. Date: Feb. 27, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Jakyoung Gu, Suwon-si (KR); Kyoungok Jung, Suwon-si (KR); Jihye Shim, Suwon-si (KR)

(21) Appl. No.: 18/751,384

(22) Filed: Jun. 24, 2024

(30) Foreign Application Priority Data
Aug. 21, 2023 (KR) 10-2023-0108720

(51) Int. Cl. H01L 21/48; G03F 7/00; G03F 7/20; H01L 23/00; H01L 23/31; H01L 23/538; H01L 25/00

(52) U.S. Cl. CPC H01L 21/481; G03F 7/2002; G03F 7/2022; G03F 7/7005; G03F 7/70458; H01L 21/4857; H01L 21/486; H01L 23/5386; H01L 24/82; H01L 25/00; H01L 23/3107; H01L 24/16; H01L 24/32; H01L 24/73; H01L 2224/16225; H01L 2224/32225; H01L 2224/73204; H01L 2224/82

(57) ABSTRACT

In a method of manufacturing a semiconductor package, a lower redistribution wiring layer having a central region and a peripheral region surrounding the central region is formed. A photosensitive insulating layer is formed on the lower redistribution wiring layer. A first light is radiated onto the photosensitive insulating layer through a first mask to form a first hardened portion on the central region. A second light is radiated onto the photosensitive insulating layer through a second mask to form a second hardened portion on the peripheral region, the second hardened portion surrounding through opening regions. Non-hardened portions in the through opening regions and at least a portion of the first hardened portion are removed. Conductive structures are formed in the through opening regions. The second hardened portion and the remainder of the first hardened portion are removed using a strip solution.

### PRIORITY STATEMENT

This application claims priority under 35 U.S.C. § 119 to Korean Patent Application No. 10-2023-0108720, filed on Aug. 21, 2023 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of stacked different semiconductor chips and a method of manufacturing the same.

### 2. Description of the Related Art

In manufacturing a Fan Out Wafer Level Package (FOWLP), a conductive structure (Cu post) may be used to electrically connect an upper chip and a lower chip. In a process of forming the conductive structure, a photosensitive insulating layer (photosensitive polymer) may be used. Because the conductive structures have relatively high heights, the photosensitive insulating layer may be formed to be thick, and accordingly, an amount of a strip solution (strip) used to remove the thick photosensitive insulating layer may be increased. Since the removal time of the photosensitive insulating layer becomes longer, the manufacturing time (UPEH, unit per equipment hour) increases.

### SUMMARY

Example embodiments provide a method of manufacturing a semiconductor package that is able to reduce the time and cost for removing a photosensitive insulating layer.

Example embodiments provide a semiconductor package produced using the above manufacturing method.

According to example embodiments, in a method of manufacturing a semiconductor package, a lower redistribution wiring layer having a central region and a peripheral region surrounding the central region is formed. A photosensitive insulating layer is formed on the lower redistribution wiring layer. A first light is radiated onto the photosensitive insulating layer through a first mask to form a first hardened portion on the central region. A second light is radiated onto the photosensitive insulating layer through a second mask to form a second hardened portion on the peripheral region, the second hardened portion surrounding through opening regions. Non-hardened portions in the through opening regions and at least a portion of the first hardened portion are removed. Conductive structures are formed in the through opening regions. The second hardened portion and the remainder of the first hardened portion are removed using a strip solution.

According to example embodiments, in a method of manufacturing a semiconductor package, a lower redistribution wiring layer having a central region and a peripheral region surrounding the central region is formed, the lower redistribution wiring layer having bonding pads that are exposed from an upper surface thereof. A photosensitive insulating layer is formed on the upper surface of the lower redistribution wiring layer. A first light having a first wavelength is radiated onto the photosensitive insulating layer through a first mask to form a first hardened portion on the central region. A second light having a second wavelength greater than the first wavelength is radiated onto the photosensitive insulating layer through a second mask to form a second hardened portion on the bonding pads, the second hardened portion surrounding through opening regions. The photosensitive insulating layer in the through opening regions and at least a portion of the first hardened portion are removed. Conductive structures are formed on the bonding pads in the through opening regions. The second hardened portion and the remainder of the first hardened portion are removed using a strip solution.

According to example embodiments, a semiconductor package includes a redistribution wiring layer having an upper surface and a lower surface opposite to each other, the redistribution wiring layer having a central region and a peripheral region surrounding the central region, the redistribution wiring layer having a plurality of first bonding pads provided in the central region and a plurality of second bonding pads provided in the peripheral region, the plurality of first and second bonding pads being exposed from the upper surface; a semiconductor chip mounted on the central region of the redistribution wiring layer, the semiconductor chip being electrically connected to the plurality of first bonding pads via conductive bumps; and a plurality of conductive structures having lower end portions bonded to the plurality of second bonding pads and upper end portions opposite the lower end portions, wherein the upper end portions are provided to be inclined horizontally closer to the central region than the lower end portions.

According to example embodiments, in a method of manufacturing a semiconductor package, a lower redistribution wiring layer having a central region and a peripheral region surrounding the central region may be formed. A photosensitive insulating layer may be formed on the lower redistribution wiring layer. A first light may be radiated onto the photosensitive insulating layer through a first mask to form a first hardened portion on the central region. A second light may be radiated onto the photosensitive insulating layer through a second mask to form a second hardened portion on the peripheral region, the second hardened portion surrounding through opening regions. Non-hardened portions in the through opening regions and at least a portion of the first hardened portion may be removed. Conductive structures may be formed in the through opening regions. The second hardened portion and the remainder of the first hardened portion may be removed using a strip solution.

In processes of forming the conductive structures on the lower redistribution wiring layer, the photosensitive insulating layer may have the first hardened portion formed in the central region, and the second hardened portion formed in the peripheral region. Since a first wavelength of the first light is shorter than a second wavelength of the second light, a first hardness of the first hardened portion irradiated with the first light may be smaller than a second hardness of the second hardened portion irradiated with the second light. Since the first hardness of the first hardened portion is relatively low, at least a portion of the first hardened portion may be removed in the process of removing the non-hardened portion to which the light is not irradiated.

Since at least part of the first hardened portion is removed together with the non-hardened portion, in the process of removing the first and second hardened portions using the strip solution, an amount of the used strip solution may be reduced, and the removal time of removing the first and second hardened portions through the strip solution may be reduced.

### BRIEF DESCRIPTION OF THE DRAWINGS

Example embodiments will be more clearly understood from the following detailed description taken in conjunction with the accompanying drawings. FIGS. 1 to 13 represent non-limiting, example embodiments as described herein.

FIG. 1 is a plan view illustrating a semiconductor package in accordance with example embodiments.

FIG. 2 is a cross-sectional view taken along the line A-A′ in FIG. 1 in accordance with example embodiments.

FIGS. 3 to 13 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

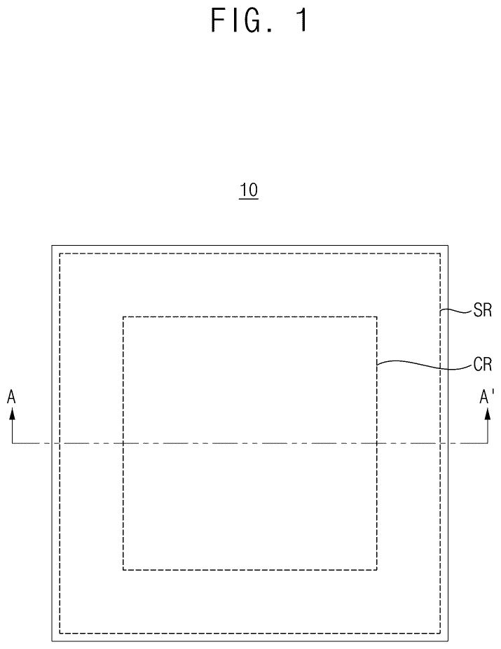

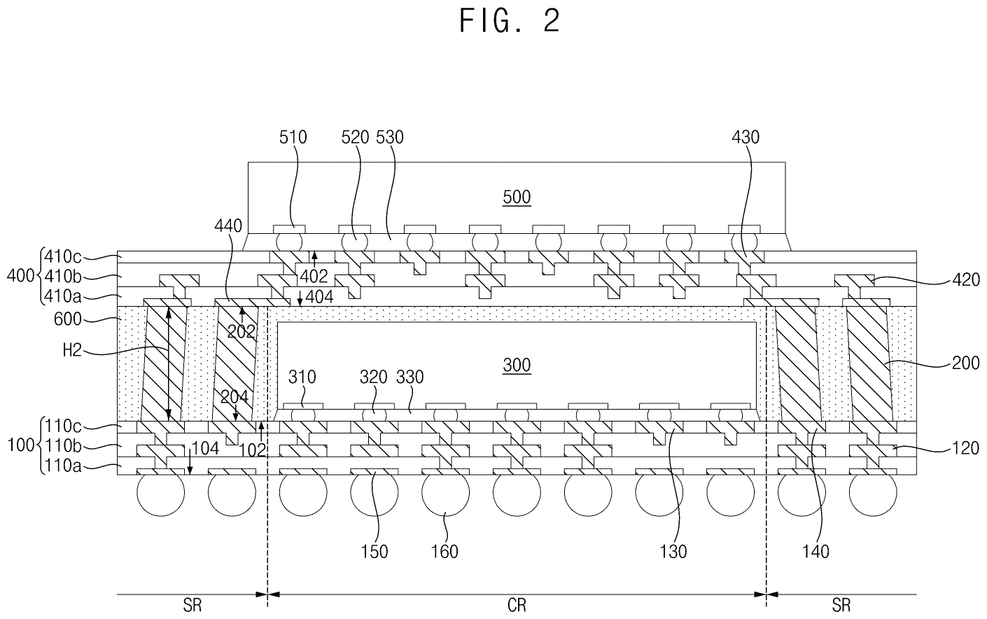

FIG. 1 is a plan view illustrating a semiconductor package in accordance with example embodiments. FIG. 2 is a cross-sectional view taken along the line A-A′ in FIG. 1.

Referring to FIGS. 1 and 2, a semiconductor package 10 may include a lower redistribution wiring layer 100, a first semiconductor chip 300 disposed on the lower redistribution wiring layer 100, an upper redistribution wiring layer 400 on the first semiconductor chip 300, and conductive structures 200 that electrically connect the lower redistribution wiring layer 100 and the upper redistribution wiring layer 400 to each other. The semiconductor package 10 may further include a molding member 600 formed on the lower redistribution wiring layer 100 and covering the first semiconductor chip 300 and a second semiconductor chip 500 disposed on the upper redistribution wiring layer 400.

In example embodiments, the lower redistribution wiring layer (first redistribution wiring layer) 100 may include a first upper surface 102 and a first lower surface 104 that are opposite to each other. The lower redistribution wiring layer 100 may include a plurality of lower redistribution wirings 120. The lower redistribution wiring layer 100 may include a plurality of first and second bonding pads 130 and 140 exposed from an upper surface (e.g., the first upper surface 102) of the lower redistribution wiring layer 100, and a plurality of first connection pads 150 provided to be exposed from a lower surface (e.g., the first lower surface 104) of the lower redistribution wiring layer 100.

The lower redistribution wiring layer 100 may include a central region CR where the first semiconductor chip 300 is mounted and a peripheral region SR surrounding the central region CR. The first bonding pads 130 for mounting the first semiconductor chip 300 may be provided in the central region CR. The second bonding pads 140 on which the conductive structures 200 are disposed may be provided in the peripheral region SR.

In example embodiments, the lower redistribution wiring layer 100 may include a plurality of lower insulating layers (insulating structural layers) 110a, 110b, 110c, and the lower redistribution wirings 120 provided in the lower insulating layers. The lower insulating layers may include or be formed of a polymer, a dielectric layer, etc. The lower redistribution wirings may electrically connect the first and second bonding pads 130 and 140 to the first connection pads 150.

In example embodiments, the lower insulating layers 110 may cover the lower redistribution wirings 120. A first insulating layer 110a may be provided at the first lower surface 104 of the lower redistribution wiring layer 100, and a third insulating layer 110c may be provided at the first upper surface 102 of the lower redistribution wiring layer 100.

In particular, the plurality of first and second bonding pads 130 and 140 may be provided in the third insulating layer 110c. Upper surfaces of the first and second bonding pads 130 and 140 may be exposed from the upper surface of the third insulating layer 110c, for example, the first upper surface 102.

The plurality of first connection pads 150 may be provided in the first insulating layer 110a. Lower surfaces of the first connection pads 150 may be exposed from the lower surface of the first insulating layer 110a, for example, the first lower surface 104. The lower redistribution wiring 120 may be formed in the lower insulating layer 110 and may electrically connect the first and second bonding pads 130 and 140 to the first connection pads 150.

The first and second bonding pads 130 and 140, the first connection pad 150, and the lower redistribution wirings 120 may include or be formed of a metal material. For example, the metal materials include nickel (Ni), antimony (Sb), bismuth (Bi), zinc (Zn), indium (In), palladium (Pd), platinum (Pt), aluminum (Al), and copper. (Cu), molybdenum (Mo), titanium (Ti), gold (Au), silver (Ag), chromium (Cr), tin (Sn), or alloys thereof.

In example embodiments, the lower redistribution wiring layer 100 may be connected to other semiconductor devices through external connection bumps 160 that serve as conductive connection members. The external connection bumps 160, also described as external connection terminals, may be formed on the first connection pads 150. For example, the external connection bumps 160 may include C4 bumps.

In example embodiments, the first semiconductor chip 300 may be disposed on the lower redistribution wiring layer 100. The first semiconductor chip 300 may be mounted on the central region CR of the lower redistribution wiring layer 100. The first semiconductor chip 300 may be mounted on the lower redistribution wiring layer 100 using a flip chip bonding method. In this case, the first semiconductor chip 300 may be mounted on the lower redistribution wiring layer 100 such that an active surface on which first chip pads 310 are formed faces the lower redistribution wiring layer 100. The first chip pads 310 of the first semiconductor chip 300 may be electrically connected to the first bonding pads 130 of the lower redistribution wiring layer 100 by first conductive bumps 320 as conductive connection members. For example, the first conductive bumps 320 may include micro bumps (uBumps).

A first adhesive member 330 may be provided between the lower redistribution wiring layer 100 and the first semiconductor chip 300. For example, the first adhesive member 330 may include or be an epoxy material, and may be described as an adhesive layer.

In example embodiments, the molding member 600 may cover the first semiconductor chip 300 and the conductive structures 200 on the lower redistribution wiring layer 100. The molding member 600 may be provided on the lower redistribution wiring layer 100 to fill a space between the lower redistribution wiring layer 100 and the upper redistribution wiring layer 400. The upper redistribution wiring layer 400 may be disposed on an upper surface of the molding member 600. For example, the molding member 600 may include or be formed of an epoxy mold compound (EMC).

In example embodiments, the conductive structures 200 penetrate the molding member 600 in a vertical direction to electrically connect the lower redistribution wiring layer 100 and the upper redistribution wiring layer 400. The conductive structures 200 may be provided in the peripheral region SR. The conductive structures 200 may extend from the lower redistribution wiring layer 100 in the vertical direction as a thickness direction of the lower redistribution wiring layer 100.

In particular, the conductive structures 200 may be electrically connected to the second bonding pads 140 of the lower redistribution wiring layer 100. The conductive structures 200 may be electrically connected to second connection pads 440 of the upper redistribution wiring layer 400. The conductive structure 200 may provide a signal movement path for electrically connecting the lower redistribution wiring layer 100 and the upper redistribution wiring layer 400. In some embodiments, the conductive structures 200 may each be in the form of a continuous, monolithic piece of material that extends from a bottom surface (e.g., 204) that contacts a top surface of the lower redistribution wiring layer 100 (e.g., a top surface of a respective second bonding pads 140) to a top surface (e.g., 202) that contacts a bottom surface of the upper redistribution wiring layer 400 (e.g., a bottom surface of a respective second connection pad 440). The conductive structures 200 may horizontally surround the first semiconductor chip 300 and may electrically connect wiring layer 100 to wiring layer 400, each of which may be referred to as a substrate.

Each of the conductive structures 200 may have an upper end portion 202 and a lower end portion 204 opposite the upper end portion 202. The upper end portions 202 of the conductive structures 200, which may be or may include upper surfaces, may be electrically connected to the second connection pads 440 of the upper redistribution wiring layer 400. The lower end portions 204 of the conductive structures 200, which may be or may include lower surfaces, may be electrically connected to the second bonding pads 140 of the lower redistribution wiring layer 100.

The upper end portions 202 of the conductive structures 200 may be provided closer to the central region CR than the lower end portions 204. Accordingly, the conductive structures 200 may have the upper end portions 202 that are inclined toward the central region CR.

The conductive structures 200 may be formed to have a second height H2 from the first upper surface 102 of the lower redistribution wiring layer 100. For example, the second height H2 may be in a range of 200 μm to 500 μm.

For example, the conductive structures 200 may have a pillar shape, a bump shape, etc. The conductive structures 200 may include or be formed of nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), etc. The conductive structures 200 may be formed by a plating process, an electroless plating process, a vapor deposition process, etc.

In example embodiments, the upper redistribution wiring layer (second redistribution wiring layer) 400 may have a second upper surface 402 and a second lower surface 404 that are opposite to each other. The upper redistribution wiring layer 400 may include a plurality of third bonding pads 430 that are exposed from the second upper surface 402 and a plurality of second connection pads 440 that are exposed from the second lower surface 404. The upper redistribution wiring layer 400 may be disposed on the upper surface of the molding member 600. At least one second semiconductor chip 500 may be disposed on the upper redistribution wiring layer 400.

The upper redistribution wiring layer 400 may be electrically connected to the lower redistribution wiring layer 100 through the conductive structures 200 that are electrically connected to the second connection pads 440. The conductive structures 200 may penetrate the molding member 600 and may electrically connect the upper redistribution wiring layer 400 and the lower redistribution wiring layer 100.

In example embodiments, the upper redistribution wiring layer 400 may include a plurality of upper insulating layers 410a, 410b, 410c, and upper redistribution wirings 420 provided in the upper insulating layers 410a, 410b, 410c. The third bonding pads 430 and the second connection pads 440 may be electrically connected by the upper redistribution wirings 420.

In particular, the plurality of third bonding pads 430 may be provided in a sixth insulating layer 410c. Upper surfaces of the third bonding pads 430 may be exposed from an upper surface of the sixth insulating layer 410c, for example, the second upper surface 402.

The plurality of second connection pads 440 may be provided in a fourth insulating layer 410a. Lower surfaces of the second connection pads 440 may be exposed from a lower surface of the fourth insulating layer 410a, for example, the second lower surface 404. The upper redistribution wiring 420 may be formed in the upper insulating layer 410 and may electrically connect the third bonding pads 430 to the second connection pads 440.

In example embodiments, the second semiconductor chip 500 may be disposed on the upper redistribution wiring layer 400. The second semiconductor chip 500 may be mounted on the upper redistribution wiring layer 400 using a flip chip bonding method. In this case, the second semiconductor chip 500 may be mounted on the upper redistribution wiring layer 400 such that an active surface on which second chip pads 510 are formed faces the upper redistribution wiring layer 400. The second chip pads 510 of the second semiconductor chip 500 may be electrically connected to the third bonding pads 430 of the upper redistribution wiring layer 400 by second conductive bumps 520 as conductive connection members or conductive connection terminals. For example, the second conductive bumps 520 may include micro bumps (uBumps).

A second adhesive member 530 may be provided between the upper redistribution wiring layer 400 and the second semiconductor chip 500. For example, the second adhesive member 530 may include an epoxy material.

Hereinafter, a method of manufacturing the semiconductor package of FIG. 1 will be described.

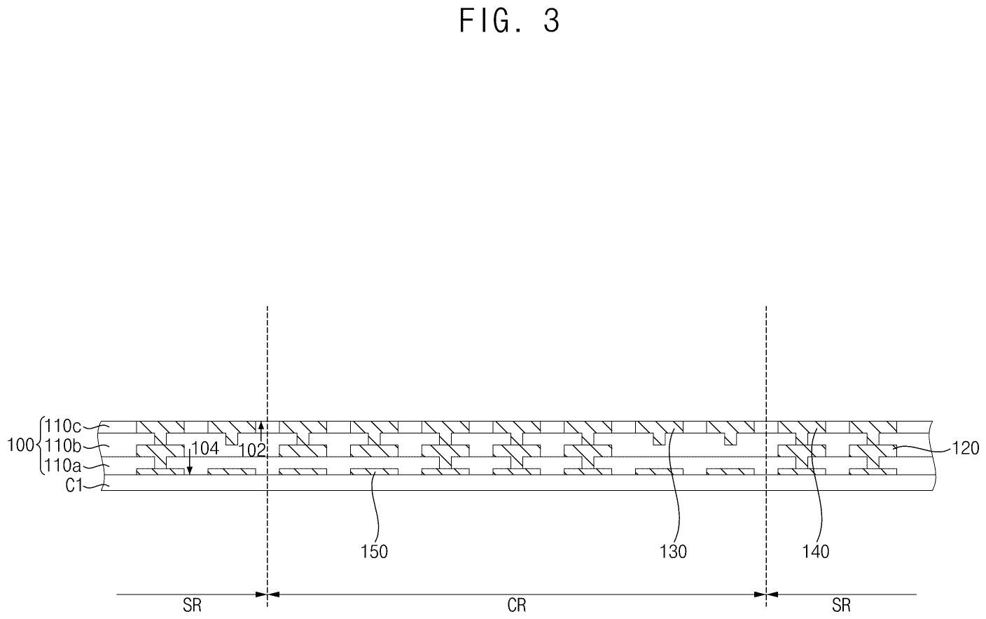

FIGS. 3 to 13 are views illustrating a method of manufacturing a semiconductor package in accordance with example embodiments.

Referring to FIG. 3, a lower redistribution wiring layer 100 of a semiconductor wafer W may be provided on a carrier substrate C1. The lower redistribution wiring layer 100 may have a central region CR and a peripheral region SR surrounding the central region CR.

First, first connection pads 150 may be formed on the carrier substrate C1, and a first insulating layer 110a may be formed on the first bonding pads 150. Then, the first insulating layer 110a may be patterned to form first openings that expose the first connection pads 150.

For example, the first insulating layer 110a may include or be a polymer, a dielectric layer, etc. In particular, the first insulating layer 110a may include or be formed of polyimide (PI), lead oxide (PbO), polyhydroxystyrene (PHS), novolac (NOVOLAC), etc. The first insulating layer 110a may be formed by a vapor deposition process, spin coating process, etc. The first bond pads may be formed by a plating process, an electroless plating process, a vapor deposition process, etc.

Then, lower redistribution wirings 120 may be formed on the first insulating layer 110a to be electrically connected to the first connection pads 150 through the first openings. The lower redistribution wirings 120 may be formed by forming a seed layer in a portion of the first insulating layer 110a and the first openings, patterning the seed layer and performing an electrolytic plating process. Accordingly, at least portions of the lower redistribution wirings 120 may contact the first connection pads 150 through the first openings.

For example, the lower redistribution wiring may include or be formed of aluminum (Al), copper (Cu), tin (Sn), nickel (Ni), gold (Au), platinum (Pt), or alloys thereof.

Then, a second insulating layer 110b may be formed on the first insulating layer 110a to cover the lower redistribution wirings 120, and then, the second insulating layer 110b may be patterned to form second openings that expose the lower redistribution wirings 120. First and second bonding pads 130 and 140 may be formed on the second insulating layer 110b to be electrically connected to the lower redistribution wirings 120 through the second openings. The first bonding pads 130 may be formed in the central region CR. The second bonding pads 140 may be formed in the peripheral region SR.

Then, a third insulating layer 110c may be formed on the second insulating layer 110b to cover the first and second bonding pads 130 and 140, and then, the third insulating layer 110c may be patterned to form third openings that expose the first and second bonding pads 130 and 140.

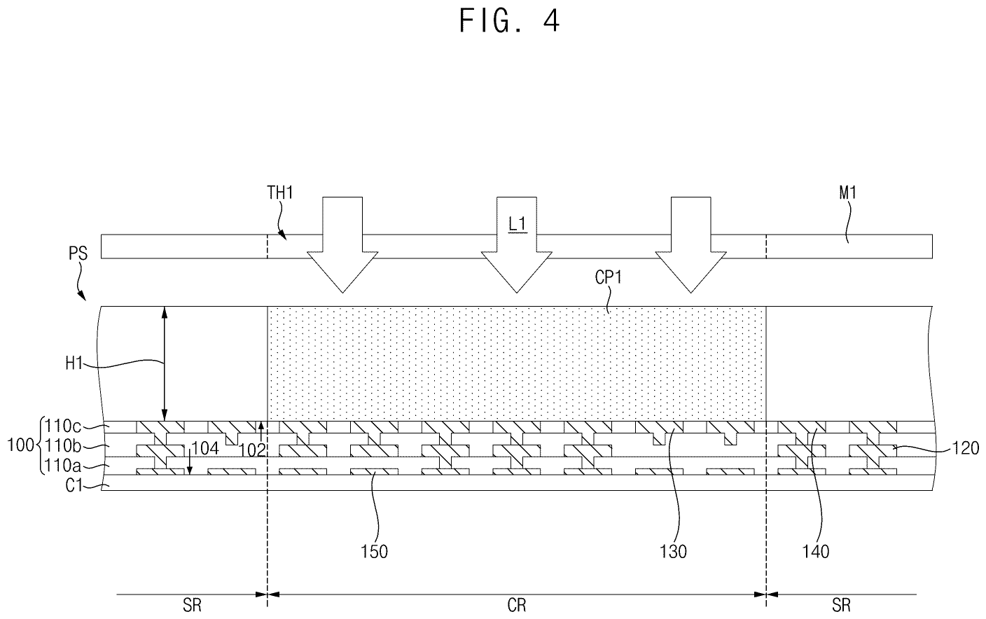

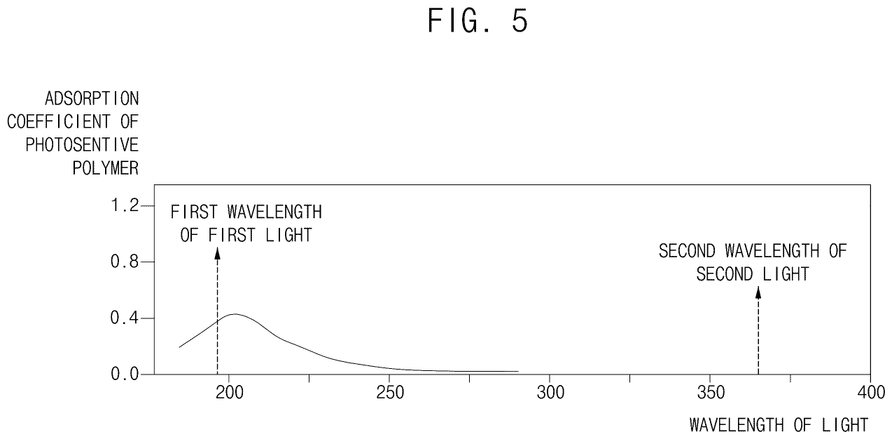

FIG. 4 is a view illustrating a process of irradiating a first light on a photosensitive insulating layer. FIG. 5 is a graph illustrating an absorption coefficient of the photosensitive insulating layer according to a wavelength of light.

Referring to FIGS. 4 and 5, first, a photosensitive insulating layer PS may be formed on the lower redistribution wiring layer 100, and a first light L1 may be irradiated on the photosensitive insulating layer PS to form a first hardened portion CP1.

In example embodiments, first, the photosensitive insulating layer PS may be formed on a first upper surface 102 of the lower redistribution wiring layer 100. The photosensitive insulating layer PS may cover the first and second bonding pads 130 and 140 that are exposed from the first upper surface 102 of the lower redistribution wiring layer 100. The photosensitive insulating layer PS may be formed to have a first height H1 from the first upper surface 102 of the lower redistribution wiring layer 100. For example, the first height H1 may be in a range of 200 μm to 500 μm.

The photosensitive insulating layers PS may include or be formed of polymer materials that harden or soften in response to light. The photosensitive insulating layer PS may include a positive photosensitive insulating material or a negative photosensitive insulating material. The positive photosensitive insulating material may break down its molecular structure, and therefore may soften, in response to light. The negative photosensitive insulating material may have a stronger molecular structure, and therefore may harden, in response to light.

For example, the photosensitive insulating layer PS may include or be formed of acrylate resin, novolac resin, PHS resin, polyimide, plumbate oxide, poly hydroxystylene, benzocyclobutene, acryl, etc.

Then, a first mask M1 may be placed on the photosensitive insulating layer PS, and the first light L1 may be radiated onto the photosensitive insulating layer PS through the first mask M1.

The first mask M1 may have a first pattern having a first through hole TH1. The first pattern may penetrate the first mask M1 in the central region CR. At least a portion of the first light L1 may pass through the first pattern (e.g., via the through hole TH1) and be radiated onto the photosensitive insulating layer PS, and at least another portion of the first light L1 may be blocked by the first mask M1. At least a portion of the photosensitive insulating layer PS irradiated by the first light L1 may react to the first light L1 to form a stronger bond in molecular structure.

As illustrated in FIG. 5, the absorption coefficient of the photosensitive insulating layer PS may vary depending on the wavelength of the light. When light having a short wavelength range is irradiated onto the photosensitive insulating layer PS, the photosensitive insulating layer PS may have a high absorption coefficient, and accordingly, light within the short wavelength range may be sufficiently absorbed by the photosensitive insulating layer PS.

The first light L1 may have a first wavelength. The first wavelength may be within the short wavelength range. The first wavelength may be within a range whose light is sufficiently absorbed by the photosensitive insulating layer PS. For example, the first wavelength may be in a range of 160 nm to 220 nm.

The first light L1 may be radiated onto the photosensitive insulating layer PS in the central region CR through the first mask M1. The first light L1 having the first wavelength may cause the formation of the first hardened portion CP1 in the photosensitive insulating layer PS. The first hardened portion CP1 may have a first hardness.

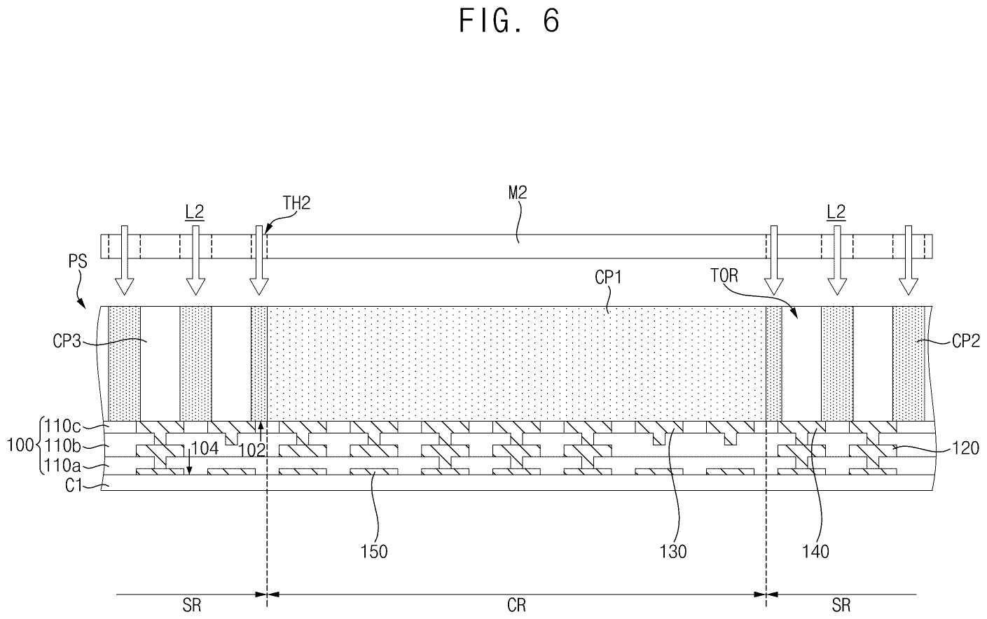

FIG. 6 is a view illustrating a process of radiating a second light onto the photosensitive insulating layer.

Referring to FIGS. 5 and 6, a second light L2 may be radiated onto the photosensitive insulating layer PS to form a second hardened portion CP2.

In example embodiments, the second mask M2 may be disposed on the photosensitive insulating layer PS, and the second light L2 may be radiated onto the photosensitive insulating layer PS through the second mask M2.

The second mask M2 may have second pattern having second through holes TH2. The second pattern may penetrate the second mask M2 in the peripheral region SR. At least a portion of the second light L2 may pass through the second pattern and be radiated onto the photosensitive insulating layer PS, and at least another portion of the second light L2 may be blocked by the second mask M2. At least a portion of the photosensitive insulating layer PS irradiated by the second light L2 may react to the second light L2 and the molecular structure may be more strongly bonded.

As illustrated in FIG. 5, when light having a long wavelength range is radiated onto the photosensitive insulating layer PS, the photosensitive insulating layer PS may have a low absorption coefficient, and accordingly, light within the long wavelength range may sufficiently pass through the photosensitive insulating layer PS.

The second light L2 may have a second wavelength. The second wavelength may be within the long wavelength range. The second wavelength may be within a range whose light sufficiently passes through the photosensitive insulating layer PS. For example, the second wavelength may be in a range of 300 nm to 400 nm.

The second light L2 may be radiated onto the photosensitive insulating layer PS in the peripheral region SR through the second mask M2. The second light L2 having the second wavelength may form the second hardened portion CP2 in the photosensitive insulating layer PS.

The second light L2 may be blocked by the second mask M2 on a through opening region TOR. The through opening region TOR may be a region that is configured to form conductive structures 200. The through opening region TOR may be formed in the photosensitive insulating layer PS on the second bonding pads 140 of the lower redistribution wiring layer 100. Since the second light L2 is blocked by the second mask M2 on the through opening region TOR, non-hardened portions CP3 may be formed in the through-opening region TOR of the photosensitive insulating layer PS.

The second hardened portion CP2 may surround the non-hardened portions CP3. The non-hardened portions CP3 may be regions where the second light L2 is blocked by the second mask M2 to form the conductive structures 200.

The second hardened portion CP2 may have a second hardness. Because the second light L2 having the second wavelength sufficiently passes through the photosensitive insulating layer PS, the second hardness of the second hardened portion CP2 irradiated by the second light L2 may be greater than the first hardness of the first hardened portion CP1 that irradiated by the first light L1.

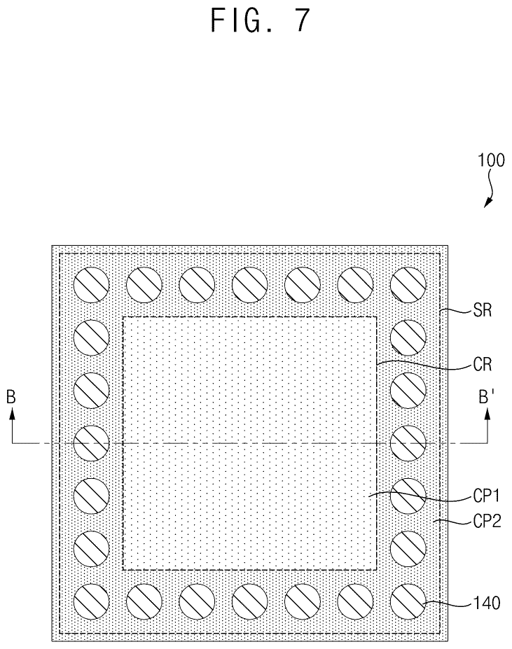

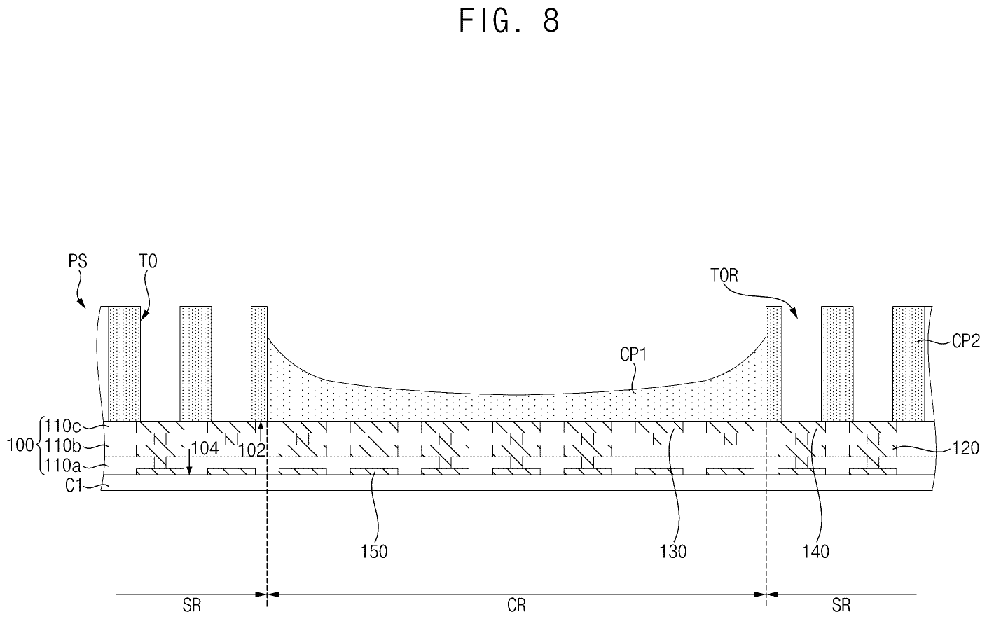

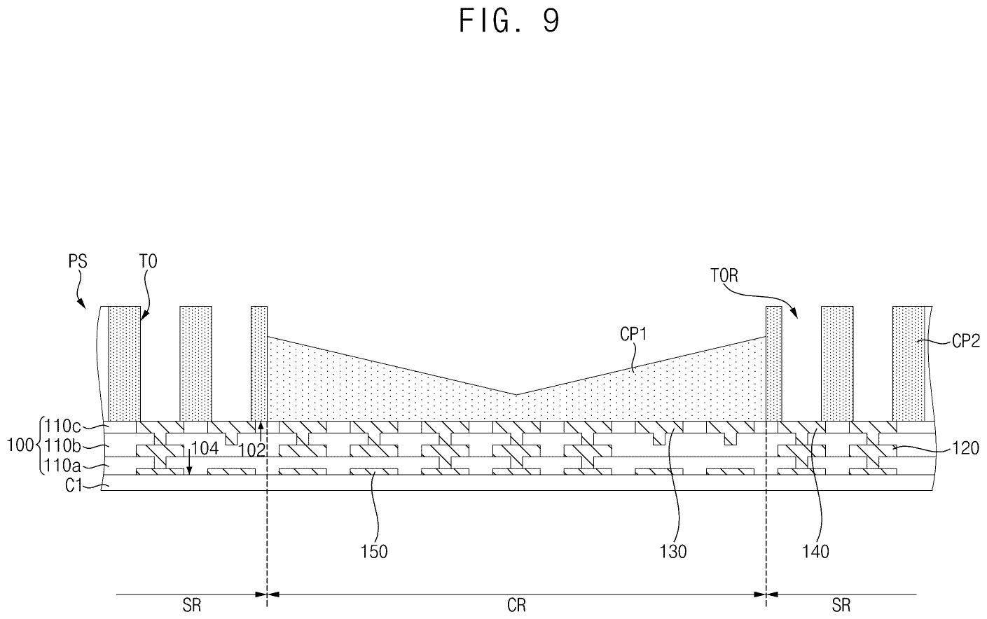

FIG. 7 is a plan view illustrating the photosensitive insulating layer having the first and second hardened portions formed on the lower redistribution wiring layer. FIGS. 8 and 9 are cross-sectional views taken along the line B-B′ in FIG. 7.

Referring to FIGS. 7 to 9, the non-hardened portion CP3 and at least a portion (e.g., a segment or section) of the first hardened portion CP1 in the through opening region TOR may be removed.

The non-hardened portion CP3 and the portion of the first hardened portion CP1 may be removed by a wet developing process using a developer solution or a dry developing process using a developing gas. While the non-hardened portion CP3 and the portion of the first hardened portion CP1 are removed by the developer or the developing gas, the second hardened portion CP2 may remain on the lower redistribution wiring layer 100.

The non-hardened portion CP3 blocked from the first and second lights L1 and L2 may have a photosensitive insulating material state and can be easily removed through the developer solution or the developer gas. Since the first hardened portion CP1 has been exposed to the first light L1 and has the first hardness, the portion of the first hardened portion CP1 may be removed through the developer or the developing gas. Since the second hardened portion CP2 has been exposed to the second light L2 and has a second hardness greater than the first hardness, the second hardened portion CP2 may maintain its structure from the developer or the developing gas.

For example, the developer may include or be tetramethylammonium hydroxide (TMAH). The developing gas may be hydrogen (H₂), chlorine (Cl₂), fluorine (F₂), bromine (Br₂), iodine (I₂), hydrogen chloride (HCl), hydrogen fluoride (HF), hydrogen bromide (HBr), hydrogen iodide (HI), etc.

The non-hardened portion CP3 may be removed through the developer or the developing gas to form through openings TO in the photosensitive insulating layer PS on the lower redistribution wiring layer 100. Alternatively, the non-hardened portion CP3 may be removed by a plasma descum process.

As illustrated in FIG. 8, the portion of the first hardened portion CP1 may be removed to form a concave hemispherical shape, which may be a curved shape in an upper portion of the photosensitive insulating layer PS in the center region CR.

Alternatively, as illustrated in FIG. 9, the portion of the first hardened portion CP1 may be removed to form a funnel shape in the upper portion of the photosensitive insulating layer PS in the center region CR. Both FIG. 8 and FIG. 9 show a recessed upper surface of the photosensitive insulating layer PS in the center region CR.

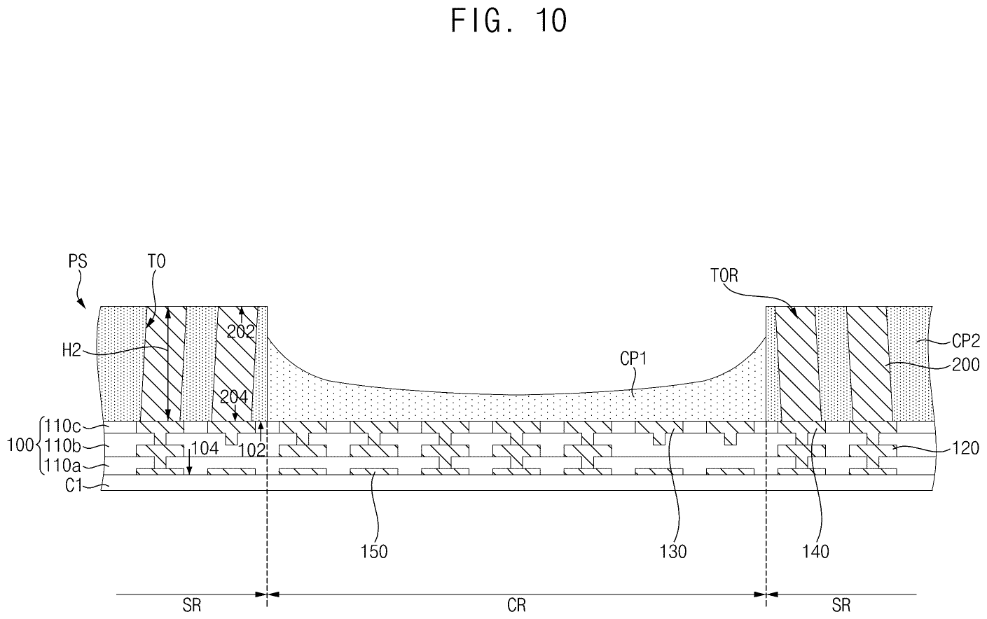

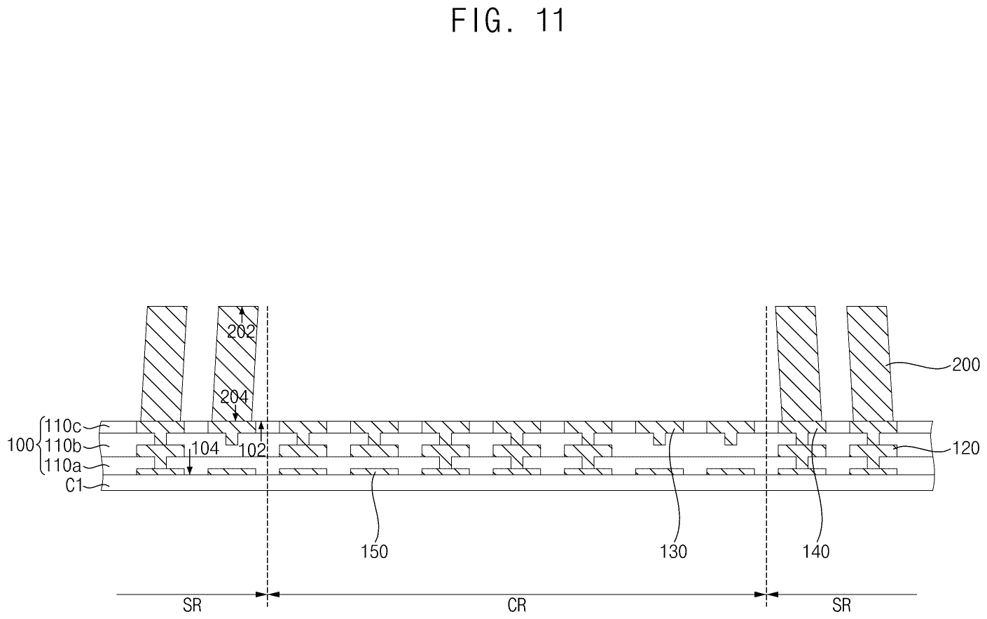

Referring to FIGS. 10 and 11, the conductive structure 200 may be formed in through openings TO in the photosensitive insulating layer PS on the through opening regions TOR, and the first and second hardened portions CP1 and CP2 may be removed through a strip solution.

In example embodiments, a plurality of conductive structures 200 may be formed on the lower redistribution wiring layer 100 to vertically penetrate the photosensitive insulating layer PS.

The conductive structures 200 may be formed in the second hardened portion CP2 of the photosensitive insulating layer PS. The conductive structures 200 may be formed on the through opening region TOR of the second hardened portion CP2. The conductive structures 200 may be formed in through openings TO that penetrate the second hardened portion CP2 in the vertical direction. The conductive structures 200 may be formed on the second bonding pads 140 of the lower redistribution wiring layer 100, for example, to contact the second ponding pads 140.

Since the second hardened portion CP2 is formed by the second light L2 having the second wavelength within the long wavelength range, the second hardened portion CP2 may have relatively high hardness. Because the second hardened portion CP2 has the relatively high hardness, a shape of the through opening TO may be maintained even when the through opening TO has a relatively large depth.

The conductive structures 200 may have upper end portions 202 and lower end portions 204 opposite the upper end portions 202. The upper end portion 202 of each conductive structure 200 may include an upper surface. The conductive structures 200 may be formed such that lower end portions 204 contact the second bonding pads 140 of the lower redistribution wiring layer 100. The lower end portion 204 of each conductive structure 200 may include a lower surface, which contacts an upper surface of a respective second bonding pad 140.

Since the portion of the first hardened portion CP1 has been removed, the upper end portions 202 of the conductive structures 200 may be formed to be inclined toward the first hardened portion CP1 during the process of forming the conductive structures 200. Accordingly, for each conductive structure 204, the upper end portions 202 (e.g., top surface) of the conductive structure 200 may be closer to the central region CR than the lower end portions 204 (e.g., bottom surface) of the conductive structure 200. The conductive structures 200 may have the upper end portions 202 that are inclined toward the central region CR.

The conductive structures 200 may be formed to have a second height H2, in a vertical direction perpendicular to the horizontal direction, from the first upper surface 102 of the lower redistribution wiring layer 100. For example, the second height H2 may be in a range of 200 μm to 500 μm. The second height H2 may refer to a height in the vertical direction between the top surface of the conductive structure 200 and a bottom surface of the conductive structure.

The conductive structures 200 may be formed within the through openings TO by a plating process. For example, the conductive structures 200 may be formed by a plating process, an electroless plating process, a vapor deposition process, etc. The conductive structures 200 may have a pillar shape (e.g., cylindrical shape), a bump shape, etc.

In example embodiments, the first and second hardened portions CP1 and CP2 may be removed using a stripping solution.

The first and second hardened portions CP1 and CP2 may be removed through a stripping process using the stripping solution. The first and second hardened portions CP1 and CP2 that remain from the developer or the developer gas may be removed from the lower redistribution wiring layer 100 through the strip solution. For example, the strip solution may be a solution that removes certain substances from a substrate, and may contain sulfuric acid and hydrogen peroxide.

Since the portion of the first hardened portion CP1 has been removed through the developer or the developer gas, an amount of the strip solution used in the strip process may be reduced, and a removal time of the photosensitive insulating layer PS may be reduced.

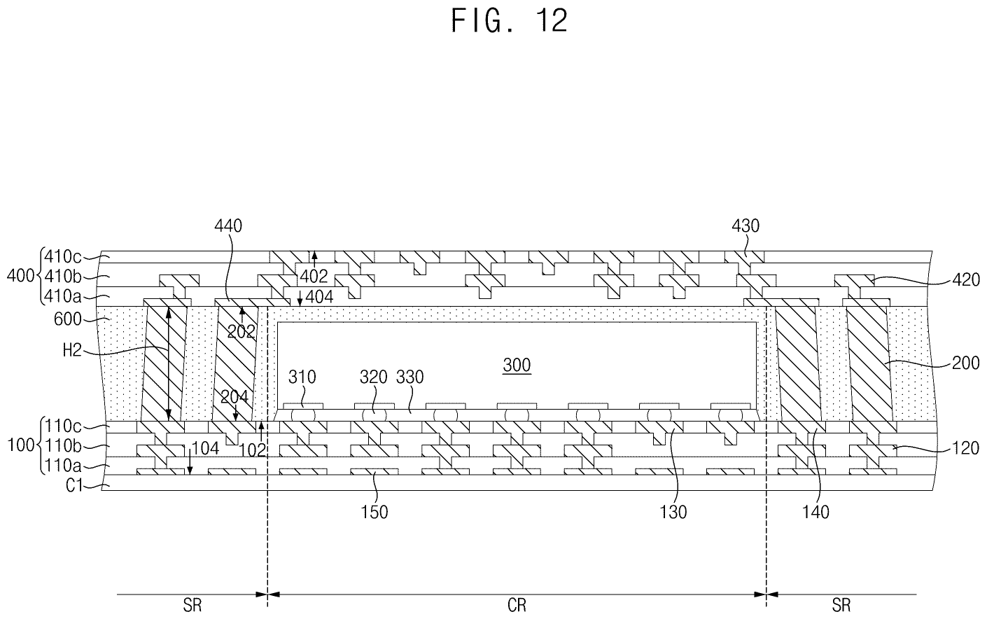

Referring to FIG. 12, a first semiconductor chip 300 may be mounted on the central region CR of the lower redistribution wiring layer 100, and an upper redistribution wiring layer 400 may be formed on the conductive structures 200. A molding member 600, also described as a molding layer, may be formed on the lower redistribution wiring layer 100 to cover the first semiconductor chip 300 and the conductive structures 200.

In example embodiments, the first semiconductor chip 300 may be mounted on the lower redistribution wiring layer 100 using a flip chip bonding method. The first semiconductor chip 300 may be mounted on the central region CR of the lower redistribution wiring layer 100. First chip pads 310 of the first semiconductor chip 300 may be electrically connected to the first bonding pads 130 of the lower redistribution wiring layer 100 by first conductive bumps 320. For example, the first conductive bumps 320 may include micro bumps (uBumps).

Then, a first adhesive member 330 may be underfilled between the lower redistribution wiring layer 100 and the first semiconductor chip 300. For example, the first adhesive member 330 may include an epoxy material to reinforce a gap between the lower redistribution wiring layer 100 and the first semiconductor chip 300.

Then, the molding member 600 may be formed on the lower redistribution wiring layer 100 to cover the first semiconductor chip 300 and the conductive structures 200. The upper end portions (e.g., upper surfaces) of the conductive structures 200 may be exposed from an upper surface of the molding member 600. For example, the molding member 600 may include or be an epoxy mold compound (EMC). The molding member 600 may include or be formed of UV resin, polyurethane resin, silicone resin, and silica filler.

Then, processes the same as or similar to the processes described with reference to FIG. 3 may be performed to form the upper redistribution wiring layer 400 on the conductive structures 200.

First, second connection pads 440 may be formed on the conductive structures 200 on the molding member 600, a third insulating layer 410a may be formed on the molding member 600 to cover the second connection pads 440, and the third insulating layer 410a may be patterned to form fifth openings that expose the second connection pads 440.

Upper redistribution wirings 420 may be formed on the fourth insulating layer 410a to be electrically connected to the second bonding pads 440 through the fifth openings. The upper redistribution wirings 420 may be formed by forming a seed layer in a portion of the fifth insulating layer 410a and the fifth openings, patterning the seed layer and then performing an electrolytic plating process. Accordingly, at least portions of the upper redistribution wirings 420 may contact the second connection pads 440 through the fifth openings.

Then, a fifth insulating layer 410b may be formed on the fourth insulating layer 410a to cover the upper redistribution wirings 420, and then, the fifth insulating layer 410b may be patterned to form sixth openings that expose the upper redistribution wirings 420. Third bonding pads 430 may be formed on the fifth insulating layer 410b to be electrically connected to the upper redistribution wirings 420 through the sixth openings.

Then, a sixth insulating layer 410c may be formed on the fifth insulating layer 410b to cover the third bonding pads 430, and then the sixth insulating layer 410c may be patterned to form seventh openings that expose the third bonding pads 430.

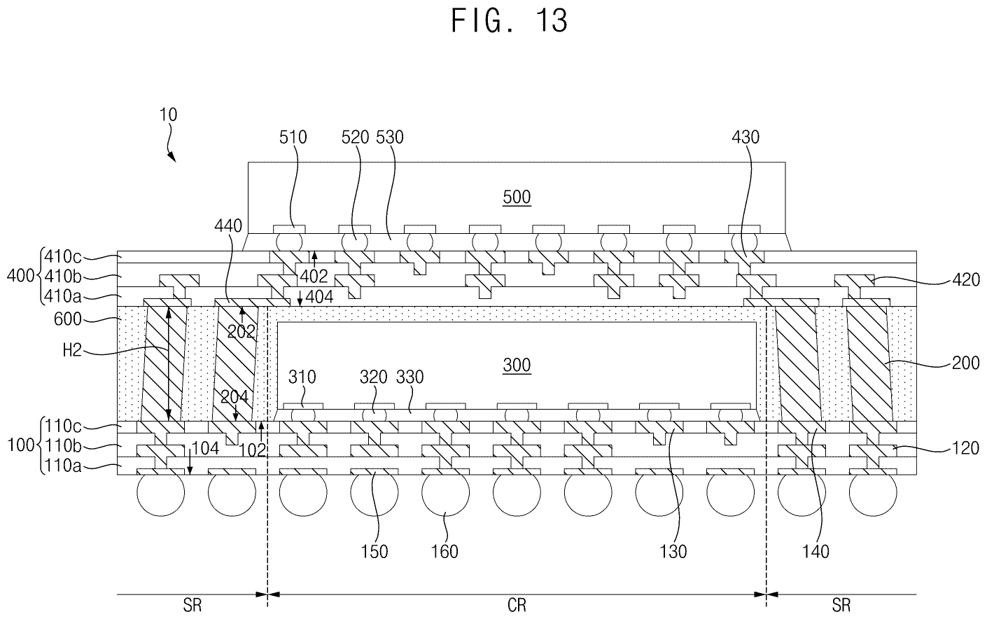

Referring to FIG. 13, the semiconductor wafer may be cut along a scribe lane region to be individualized, and processes the same as or similar processes described with reference to FIG. 12 may be performed to mount a second semiconductor chip 500 on the upper redistribution wiring layer 400, and an external connection bump 160 may be disposed on the first connection pads 150 so the semiconductor package 10 can be completed.

In example embodiments, the second semiconductor chip 500 may be mounted on the upper redistribution wiring layer 400 using a flip chip bonding method. Second chip pads 510 of the second semiconductor chip 500 may be electrically connected to the third bonding pads 430 of the upper redistribution wiring layer 400 through second conductive bumps 520. For example, the second conductive bumps 520 may include a micro bumps (uBumps).

Then, a second adhesive member 530 may be underfilled between the upper redistribution wiring layer 400 and the second semiconductor chip 500. For example, the second adhesive member 530 may include or be an epoxy material to reinforce a gap between the upper redistribution wiring layer 400 and the second semiconductor chip 500. The second adhesive member 530 may be referred to as an underfill layer, or adhesive layer.

Then, the external connection bumps 160 may be formed on the first connection pads 150 of the lower redistribution wiring layer 100.

The external connection bumps 160 may be formed on the first connection pads 150, respectively. In particular, after a photoresist pattern having temporary openings is formed and the temporary openings of the photoresist pattern are filled with a conductive material, the photoresist pattern may be removed and a reflow process may be performed to form the external connection bumps 160. Alternatively, the external connection bumps 160 may be formed by a screen printing method, a deposition method, or the like. For example, the external connection bumps 160 may include a C4 bump.

In some embodiments, rather than cutting the semiconductor wafer W prior to mounting the semiconductor chip 500, the semiconductor wafer W may be cut to complete the semiconductor package 10 of FIG. 1 after forming and reflowing the external connection bumps 160. The semiconductor wafer W may be cut along the scribe lane region. The semiconductor wafer W may be cut by a dicing process (e.g., using a mechanical or laser sawing process).

As described above, the photosensitive insulating layer PS may have the first hardened portion CP1 formed in the central region CR and the second hardened portion CP2 formed in the peripheral region SR. Since the first wavelength of the first light L1 is shorter than the second wavelength of the second light L2, the first hardness of the first hardened portion CP1 irradiated with the first light L1 may be smaller than the second hardness of the second hardened portion CP2 irradiated with the second light L2. Since the first hardness of the first hardened portion CP1 is relatively low, at least a portion of the first hardened portion CP1 may be removed in the process of removing the non-hardened portion CP3 to which the light is not radiated.

Since the at least part of the first hardened portion CP1 is removed together with the non-hardened portion CP3, in the process of removing the first and second hardened portions CP1 and CP2 through the strip solution, the amount of the used strip solution may be reduced, and the removal time of removing the first and second hardened portions CP1 and CP2 through the strip solution may be reduced.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of the invention as defined in the claims.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

1. A method of manufacturing a semiconductor package, the method comprising:
forming a lower redistribution wiring layer having a central region and a peripheral region surrounding the central region;
forming a photosensitive insulating layer on the lower redistribution wiring layer;
radiating a first light onto the photosensitive insulating layer through a first mask to form a first hardened portion on the central region;
radiating a second light onto the photosensitive insulating layer through a second mask to form a second hardened portion on the peripheral region, the second hardened portion surrounding through opening regions;
removing non-hardened portions in the through opening regions and at least a portion of the first hardened portion;
forming conductive structures in the through opening regions; and
removing the second hardened portion and the remainder of the first hardened portion using a strip solution.

2. The method of claim 1, wherein the photosensitive insulating layer includes at least one selected from acrylate resin, novolac resin, and PHS resin.

3. The method of claim 1, wherein the first light has a first wavelength, and the second light has a second wavelength greater than the first wavelength.

4. The method of claim 3, wherein the first wavelength of the first light is within a range of 160 nm to 220 nm.

5. The method of claim 3, wherein the second wavelength of the second light is within a range of 300 nm to 400 nm.

6. The method of claim 1, wherein the first hardened portion has a first hardness, the second hardened portion has a second hardness, and the second hardness is greater than the first hardness.

7. The method of claim 1, wherein removing the portion of the first hardened portion comprises forming a recess in an upper portion of the photosensitive insulating layer.

8. The method of claim 1, wherein forming the conductive structures in the through opening regions includes forming upper end portions of the conductive structures to be inclined toward the central region.

9. The method of claim 1, further comprising:
mounting a first semiconductor chip in the central region of the lower redistribution wiring layer; and
forming an upper redistribution wiring layer on the conductive structures.

10. The method of claim 9, further comprising:
forming a molding member between the lower redistribution wiring layer and the upper redistribution wiring layer; and
mounting a second semiconductor chip on the upper redistribution wiring layer.

11. A method of manufacturing a semiconductor package, the method comprising:
forming a lower redistribution wiring layer having a central region and a peripheral region surrounding the central region, the lower redistribution wiring layer having bonding pads that are exposed from an upper surface thereof;
forming a photosensitive insulating layer on the upper surface of the lower redistribution wiring layer;
radiating a first light having a first wavelength onto the photosensitive insulating layer through a first mask to form a first hardened portion in the central region;
radiating a second light having a second wavelength greater than the first wavelength onto the photosensitive insulating layer through a second mask to form a second hardened portion on the bonding pads, the second hardened portion surrounding through opening regions;
removing the photosensitive insulating layer in the through opening regions and at least a portion of the first hardened portion;
forming conductive structures on the bonding pads in the through opening regions; and
removing the second hardened portion and the remainder of the first hardened portion using a strip solution.

12. The method of claim 11, wherein the photosensitive insulating layer includes at least one selected from acrylate resin, novolac resin, and PHS resin.

13. The method of claim 11, wherein the first wavelength of the first light is within a range of 160 nm to 220 nm.

14. The method of claim 11, wherein the second wavelength of the second light is within a range of 300 nm to 400 nm.

15. The method of claim 11, wherein the first hardened portion has a first hardness, the second hardened portion has a second hardness, and the second hardness is greater than the first hardness.

16. The method of claim 11, wherein removing the portion of the first hardened portion comprises forming a recess in an upper portion of the photosensitive insulating layer.

17. The method of claim 11, wherein forming the conductive structures on the bonding pads includes forming upper end portions of the conductive structures to be inclined toward the central region.

18. The method of claim 11, further comprising:
mounting a first semiconductor chip on the central region of the lower redistribution wiring layer; and
forming an upper redistribution wiring layer on the conductive structures.

19. The method of claim 18, further comprising:
forming a molding member between the lower redistribution wiring layer and the upper redistribution wiring layer; and
mounting a second semiconductor chip on the upper redistribution wiring layer.

20. A method of manufacturing a semiconductor package, the method comprising:
forming a lower redistribution wiring layer having a central region and a peripheral region surrounding the central region, the lower redistribution wiring layer having bonding pads that are exposed from an upper surface thereof;
forming a photosensitive insulating layer on the upper surface of the lower redistribution wiring layer;
forming a first hardened portion having a first hardness on the central region by radiating a first light having a first wavelength on the photosensitive insulating layer;
forming a second hardened portion having a second hardness higher than the first hardness by radiating a second light having a second wavelength greater than the first wavelength onto the photosensitive insulating layer, the second hardened portion surrounding through opening regions on the bonding pads;
removing the photosensitive insulating layer on the through opening regions and at least a portion of the first hardened portion; and
forming conductive structures on the bonding pads in the through opening regions; and
removing the second hardened portion and the remainder of the first hardened portion through a strip solution.

21. (canceled)
